(19) United States
(12) Patent Application Publication
(10) Pub. No.: US 2026/0022461 A1
(43) Pub. Date: Jan. 22, 2026

(54) MODULAR VAPOR DELIVERY SYSTEM FOR SEMICONDUCTOR PROCESS TOOLS

(71) Applicant: Lam Research Corporation, Fremont, CA (US)

(72) Inventors: Christopher Matthew JONES, Woodburn, OR (US); Aaron DURBIN, Portland, OR (US); Thadeous BAMFORD, Portland, OR (US); John Folden STUMPF, Wilsonville, OR (US); Paul C. LEMAIRE, Portland, OR (US); Bryce Isaiah EDMONDSON, Portland, OR (US); Joseph R. ABEL, West Linn, OR (US)

(73) Assignee: Lam Research Corporation, Fremont, CA (US)

(21) Appl. No.: 19/100,169

(22) PCT Filed: Aug. 21, 2023
(86) PCT No.: PCT/US2023/072597

§ 371 Date: Jan. 31, 2025

Related U.S. Application Data
(60) Provisional application No. 63/373,982, filed on Aug. 30, 2022.

(51) Int. Cl. C23C 16/455; C23C 16/448; C23C 16/52

(52) U.S. Cl. CPC C23C 16/45561; C23C 16/4481; C23C 16/52

(57) ABSTRACT

A modular vapor delivery system comprising a flow control component module that comprises a first inlet port and a second inlet port. a liquid flow controller coupled to an outlet port of the flow control component module, and a vaporizer module coupled to an outlet port of the liquid flow controller.

### CLAIM FOR PRIORITY

This application claims priority to U.S. Provisional Patent Application No. 63/373,982, filed on Aug. 30, 2022, titled “MODULAR VAPOR DELIVERY SYSTEM FOR SEMICONDUCTOR PROCESS TOOLS,” and which is incorporated by reference in entirety.

### BACKGROUND

Process tools are used to perform treatments such as deposition and etching of film on semiconductor wafer substrates. These process tools may comprise a vacuum chamber in which chemical vapor deposition (CVD) and atomic layer deposition (ALD) processes may be performed. Precision deposition processes such as ALD use precise delivery of precursor gases and vapors (collectively, process gases) into the vacuum chamber through a gas distribution showerhead within the vacuum chamber. These processes employ process gases comprising an inert carrier gas and one or more vaporized precursor substances. The process gas may be formed by vaporizing one or more liquid precursors and then mixing the vapors with the carrier gas. In many processes, multiple precursor species may be delivered to a process chamber in a specific ratio of concentrations. Conventionally, individual precursor vapors are handled in separate flow paths within a vapor delivery apparatus prior to entering a process chamber where the individual gases may be mixed and distributed through the gas distribution showerhead, for example.

Precursor vapors are generally generated by heating a precursor substance in the liquid or solid state. Vaporization temperatures may be greater than 100° C. Generally, care must be taken to avoid cold spots along the gas flow path within the block and between the block and the showerhead. Once formed, the precursor vapors may flow along multiple flow paths that are heated to maintain the precursors in the vapor state. the process gas streams may pass through a system of flow components such as filters, mixing chambers, and flow control valves. These flow components are generally heated as well to potential condensation of precursor vapors. For greater efficiency and cost reduction, a single flow path to carry multiple precursor species may be desired. Thus, a compact and configurable modular vapor delivery system may be desired to provide handling of two or more process precursor vapors and perform all functions of more complex conventional vapor delivery systems.

### BRIEF DESCRIPTION OF THE DRAWINGS

The material described herein is illustrated by way of example and not by way of limitation in the accompanying figures. For simplicity and clarity of illustration, elements illustrated in the figures are not necessarily drawn to scale and exact locations. For example, the dimensions of some elements may be exaggerated relative to other elements for clarity. Also, various physical features may be represented in their simplified “ideal” forms and geometries for clarity of discussion, but it is nevertheless to be understood that practical implementations may only approximate the illustrated ideals. For example, smooth surfaces and square intersections may be drawn in disregard of finite roughness, corner-rounding, and imperfect angular intersections characteristic of structures formed by nanofabrication techniques. Further, where considered appropriate, reference labels have been repeated among the figures to indicate corresponding or analogous elements.

FIG. 1 illustrates a block diagram of a modular vapor delivery system, comprising a flow control components module and a vaporizer module, according to at least one implementation of the disclosure.

FIG. 2 illustrates a block diagram of the modular vapor delivery system of FIG. 1, comprising a chemistry ampoule internally coupled to the flow control components module, according to at least one implementation of the disclosure.

FIG. 3 illustrates a block diagram of the modular vapor delivery system of FIG. 1, supplied by an external chemistry storage and delivery unit, according to at least one implementation of the disclosure.

FIG. 4 illustrates a block diagram for a system comprising a modular vapor delivery system, according to at least one implementation of the disclosure.

FIG. 5 illustrates a process flow chart illustrating an exemplary method for operating a modular vapor delivery system, according to at least one implementation of the disclosure.

### DETAILED DESCRIPTION

Disclosed herein is a modular vapor delivery system that comprises a-heated conduit for transporting multiple precursor vapors to a process chamber of a semiconductor process tool. The modular vapor delivery system may comprise a flow control component module coupled to a vaporizer module. The vaporizer module may be operable to vaporize a liquid stream comprising mixtures of one or more precursor substances. In at least one implementation, mixing of multiple single-component precursor streams may occur within the flow control component module. In at least one implementation, the precursor mixture is supplied by an external chemistry storage and delivery unit that is physically separate from the modular vapor delivery system. In at least one implementation, a chemistry ampoule is configured to contain a component or multi-component precursor liquid. The chemistry ampoule may be a module on modular vapor delivery system.

The modules of the modular vapor delivery system may be mounted on a board or platform. In at least one implementation, a cabinet enclosure may house the modular vapor delivery system. Liquid delivery lines from the chemistry storage and distribution unit may be routed within an exhaust duct that is coupled to an enclosure housing the modular vapor delivery system. The precursor mixture may be transferred (e.g., under pressure) as a liquid stream from the chemistry storage and delivery unit (e.g., external to the modular vapor delivery system) or from the chemistry ampoule to the flow control component module. From the flow control component module, the liquid stream may be transferred to the vaporizer module. The liquid stream may be vaporized within the vaporizer module such that the resulting vapor comprises vapors of the individual precursor species in the same proportions as they were in the liquid state.

In at least one implementation, the vaporizer module is a final stage of the modular vapor delivery system. Such a configuration may enable the vaporizer module to be coupled directly to a process chamber of a semiconductor process tool, for example, by a heated delivery conduit that prevents condensation of the precursor vapors within the heated vapor delivery line. Thus, the abundance ratio (e.g., molar ratio, mass or volumetric concentration ratio) of the precursor vapors may be maintained while in transit to a distribution point within the process chamber, such as a gas distribution showerhead.

In at least one implementation, the vaporizer module may supply sufficient heat and temperature control as a self-contained device for vaporizing a multi-component liquid stream. In at least one implementation, the vaporizer module is the final stage of the modular vapor delivery system. Employing the vaporizer module as the final stage may enable a significant design simplification of the modular vapor delivery system. For example, heating of vapor handling components may normally entail complex systems of heating elements such as cartridge heaters, temperature sensors, temperature controllers, as well as insulation of gas delivery lines. Such complex design for temperature control is substantially eliminated by the disclosed modular vapor delivery system. Vapors may be introduced to the process chamber through a heated vapor delivery line following the vaporizer module. Because of the simple geometry involved, employment of a heated vapor delivery line may also significantly reduce risk of condensation of vapors prior to delivery into the process chamber.

In at least one implementation, precursor vapors may be mixed with inert carrier gases such as nitrogen or argon. Precursors may comprise a small fraction of the carrier gas or precursor mixture. Multicomponent precursors may comprise two or more components in a specific molar ratio, for example. The carrier gas may be a make-up gas mixed with the precursor mixture to dilute the individual precursor substances to predetermined concentrations. In at least one implementation, the carrier gas may also include reactive gases such as hydrogen, ammonia, hydrazine, oxygen, ozone, or water vapor. In general, precursor substances may be heated to elevated temperatures to vaporize them into the gas phase. The elevated temperature may also enable surface reactions within a process (e.g., a deposition or etching) chamber.

In at least one implementation, the modular vapor distribution system comprises a chemistry ampoule. The chemistry ampoule may be a liquid-compatible vessel integral with the modular vapor distribution system. The chemistry ampoule may be operable to contain one or more precursor compounds in a liquid mixture. In at least one implementation, the chemistry ampoule module may be pressurized to cause the liquid contents to flow into the liquid flow control component module. As an example, in at least one implementation, the chemistry ampoule module may comprise an inlet port that is coupled to a valved inert gas line. The inert gas line may carry inert carrier gas (e.g., argon or nitrogen) into the chemistry ampoule module for pressurization of the liquid content. In at least one implementation, the pressurized liquid content may flow through an outlet port of the chemistry ampoule and into a valved liquid line that is coupled to an inlet port of the liquid flow control components module. The gas and liquid delivery lines may comprise in-line valves to enable on-demand flow by opening and closing off flow of inert gas, liquid contents, or both.

In at least one implementation, liquid precursor may be supplied to the modular vapor delivery system by an external chemistry storage and delivery unit. In at least one implementation, the external vapor delivery system may be coupled to the modular vapor delivery system by one or more liquid delivery lines. In at least one implementation, the one or more liquid delivery lines may be routed through an exhaust duct. The exhaust duct may be coupled to an enclosure housing the modular vapor delivery system for ventilation of the enclosure.

In at least one implementation, a remote lockout tagout (LOTO) valve is coupled in-line with the one or more liquid delivery lines. The in-line LOTO valve may be a shut-off valve to isolate the modular vapor delivery system from the external liquid chemistry storage and delivery unit. For example, the LOTO valve may be employed for maintenance or emergency purposes. The LOTO valve may be located on the process tool to allow easy access. In at least one implementation, the LOTO valve may be housed in an enclosure that is in-line with an exhaust duct.

In at least one implementation, one or more degas modules may be in-line with the one or more liquid delivery lines coupled to a chemistry storage and delivery unit. In at least one implementation, the degas modules may follow the LOTO valve in the following order: external chemistry storage and delivery unit, LOTO valve, and degas module. The one or more degas modules may remove bubbles of entrained gas from the liquid precursors or liquid precursor mixture entering the liquid flow control module.

In some instances, in the following description, well-known methods and devices are shown in block diagram form, rather than in detail, to avoid obscuring the present disclosure. Reference throughout this specification to “an implementation” or “one implementation” or “at least one implementation” means that a particular feature, structure, function, or characteristic described in connection with the implementation is included in at least one implementation of the disclosure. Thus, the appearances of the phrase “in an implementation” or “in one implementation” or “at least one implementation” in various places throughout this specification are not necessarily referring to the same implementation of the disclosure. Furthermore, the particular features, structures, functions, or characteristics may be combined in any suitable manner in one or more implementations. For example, a first implementation may be combined with a second implementation anywhere the particular features, structures, functions, or characteristics associated with the two implementations are not mutually exclusive.

Here, “coupled” and “connected,” along with their derivatives, may be used to describe functional or structural relationships between components. These terms are not intended as synonyms for each other. Rather, in particular implementations, the term “connected” may be used to indicate that two or more elements are in direct physical, optical, or electrical contact with each other. Here, “coupled” may be used to indicate that two or more elements are in either direct or indirect (with other intervening elements between them) physical, electrical or in magnetic contact with each other, and/or that the two or more elements co-operate or interact with each other (e.g., as in a cause and effect relationship). Here, “coupled” may also generally refer to direct attachment of one electronic component to another. An electric or magnetic field may couple one component to another, where the field is controlled by one component to influence the other in some manner.

Here, “over,” “under,” “between,” and “on” may generally refer to a relative position of one component or material with respect to other components or materials where such physical relationships are noteworthy. Unless these terms are modified with “direct” or “directly,” one or more intervening components or materials may be present. Similar distinctions are to be made in the context of component assemblies. As used throughout this description, and in the claims, a list of items joined by the term “at least one of” or “one or more of” can mean any combination of the listed terms.

Here, “adjacent” may generally refer to a position of a thing being next to (e.g., immediately next to or close to with one or more things between them) or adjoining another thing (e.g., abutting it).

Here, “module” may generally refer to a self-contained grouping of components that may function together to perform particular tasks. The components may be assembled on a common block or chassis. An enclosure may be employed to house the module.

Here, “modular” may generally refer to an adjective describing a system that comprises one or more modules. The modules may be interchangeable or replaceable.

Here, “process gas” may generally refer to an inert or reactive carrier gas, such as argon, nitrogen, oxygen, or hydrogen. The substance may be considered a gas if the substance is in the gaseous state at room temperature. A process gas may also contain or be a vapor of a precursor substance. In a process gas, the precursor substance is generally in a vapor state at an elevated temperature, either by sublimation or boiling. A vapor may condense or crystallize at temperatures below a critical temperature.

Here, “carrier gas” may generally refer to an inert or reactive gas that is mixed with one or more vapors, for example, to dilute the one or more vapors and carry them within a flow composed mostly of the carrier gas.

Here, “liquid state” may generally refer to a substance that is liquid at or near room temperature and above.

Here, “vapor state” may generally refer to a substance that has been changed from a liquid state to a gas state. The substance may be heated to its boiling point to transform it from the liquid state to the gas state, or heated to its sublimation point to transform it by sublimation from the solid state to the gas state.

Here, “precursor substance” may generally refer to a chemical substance that can undergo a surface or gas phase reaction to transform into a solid film on a surface during a deposition process. The precursor may be a chemical reactant that is involved with the surface or gas phase reaction to create a surface film.

Here, “precursor liquid” may generally refer to a precursor substance in a liquid state at room temperature, well below its vaporization temperature, for example.

Here, “precursor vapor” may generally refer to a precursor substance that has been heated to its vaporization temperature to transform it from a condensed state, liquid, or solid, to its vapor state. The precursor substance may be heated to its boiling temperature or sublimation temperature, for example.

Here, “mass flow controller” (MFC) may generally refer to a device that is operable to control the mass flow rate of liquids or gases.

Here, “liquid flow controller” (LFC) may generally refer to a flow control device specific to controlling flow rates of liquids.

Here, “surface mount substrate,” or “substrate,” may generally refer to a plate or block having a subsurface flow passage for transport of gases or liquids. The substrate comprises a mounting surface, upon which surface mountable valves, filters, pressure regulators, gauges, tubing couplers, etc., may be bolted. The mounting surface comprises a plurality of apertures that align to inlet ports and outlet ports on the bottom flanges of the surface mount components. The apertures are fluidically coupled to the internal flow path. By alignment of fluid ports on the bottoms of the surface mount components to the surface apertures, the surface mount components may be in-line with the subsurface flow passage. The coupling may be serial, so that the fluid may be forced to flow through the surface mount component.

Here, “surface mount component” may generally refer to modular valves, flow controllers, gauges, filters, pressure regulators, and the like, that may comprise a base flange that bolts onto a surface mount substrate. The surface mount substrate may be configured to flow a gas or liquid through a subsurface flow passage to which a series of apertures along a row or column are fluidically coupled by tapping into the flow path at intervals along the flow passage. The apertures may be aligned to inlet and outlet ports on the bottom of multiple surface mount components, where liquids or gases may serially enter the surface mount components fluidically coupled to the same subsurface flow passage. Multiple surface mount components may be coupled to the same subsurface flow passage by attaching to the substrate along a row or column of apertures following the subsurface flow path.

Here, “flow control component” may generally refer to surface mount components or free-standing flow control components such as valves, filters, and mass flow controllers that may control gas and liquid flow.

Here, “flow control component module” may generally refer to a module of a modular system, for example, a modular vapor delivery system. The flow control component module may comprise one or more flow control components.

Here, “vaporizer module” may generally refer to a vaporizer device operable to supply heat of vaporization to a component liquid stream, causing vaporization of all components of the liquid stream.

Here, “coupled” may generally refer to components that are coupled in such a way that fluids (e.g., gases or liquids) may flow from one component to the other. The term “fluidically coupled” may also have the same meaning. For example, a conduit may be coupled (or fluidically coupled) to a vessel when it opens into the interior of the vessel, enabling a fluid to flow between the conduit and the vessel.

Here, “reservoir” may generally refer to a vessel for containing a gas or liquid.

Here, “chemistry ampoule” may generally refer to a reservoir (ampoule) operable to contain a liquid substance.

Here, “vapor delivery line” may generally refer to metal, glass or polymer tubing that is employed to transport gases and vapors from one point to another within a system comprising vapor supply or generation points.

Here, “carrier gas line” may generally refer to a gas delivery line that transports carrier gases.

Here, “liquid delivery line” may generally refer to a metal, glass, or polymer tubing that is employed to transport liquids from one point to another within a system comprising a liquid supply.

Here, “duct” may generally refer to a conduit.

Here, “exhaust duct” may generally refer to a conduit coupled to an exhaust system. The exhaust system may be a ventilation system having active air convection such that a suction is created within an enclosed space, enabling evacuation of accumulated unwanted vapors and gases within that enclosed space and replenishment of the air within the space.

Here, “valve” may generally refer to a device that may gate the flow of a fluid such as a liquid or gas. For example, a gate valve, a butterfly valve, or a ball valve may be fully opened or closed. A valve may also adjust the flow of the fluid between fully open or closed.

Here, “divert valve” may generally refer to a three-way valve coupled to a vacuum exhaust. The divert valve may be operable to switch flow of gas or liquid within one line to the vacuum exhaust.

Here, “lockout tagout (LOTO) valve” may generally refer to a type of shut-off valve that may be employed to isolate one or more sections, modules or portions of a liquid or gas-handling apparatus from other sections, modules or portions of the same or different apparatus. This type of valve has features which allow it to be secured in a given state (e.g., closed) by an external locking mechanism.

Here, “inlet port” may generally refer to a port of a device, such as a vaporizer module, valve, mass flow controller, etc., to which a conduit is connected and delivers an incoming liquid or gas flow from the conduit.

Here, “outlet port” may generally refer to a port of a device, such as a vaporizer module, valve, mass flow controller, etc., to which a conduit is connected and from which an outgoing flow of a liquid or gas issues into the conduit.

Here, “semiconductor process tool” may generally refer to an apparatus comprising a vacuum chamber wherein integrated electronic circuits and micro electromechanical systems (MEMS) devices may be fabricated on semiconductor wafers. The semiconductor wafers may be treated by a variety of deposition and etch processes that are typically conducted in a high vacuum. A high vacuum may be developed within the vacuum chamber.

Here, “showerhead” may generally refer to a gas dispensing manifold that is employed in the vacuum chamber of a semiconductor process tool. The showerhead may comprise a plurality of apertures through which process gases may be dispersed into the vacuum chamber. The showerhead may be fed by process gases passing through a gas conditioning assembly or directly from a process gas source. A showerhead may be employed in a semiconductor process tool vacuum chamber.

Here, “conduit” may generally refer to pipe or tubing that conveys gas or liquid.

Here, “vacuum chamber” may generally refer to a chamber that is pumped down to a high vacuum. Vacuum chambers may be employed in semiconductor process tools for fabrication of integrated circuits and MEMS devices. Deposition, cleaning, and etch processes are most commonly carried out in the vacuum chamber.

Here, “process chamber” may generally refer to a vacuum chamber dedicated to the fabrication of semiconductor integrated circuits, for example. A process chamber may be part of a process tool, comprising a showerhead for introducing gases and vapors into the process chamber. A process chamber may also generally comprise a wafer chuck for supporting a semiconductor or insulator wafer as a substrate for chemical vapor deposition or etching processes.

Unless otherwise specified in the explicit context of their use, “substantially equal,” “about equal,” and “approximately equal” may generally mean that there is no more than incidental variation between two things so described. In the art, such variation is typically no more than +/−10% of the referred value.

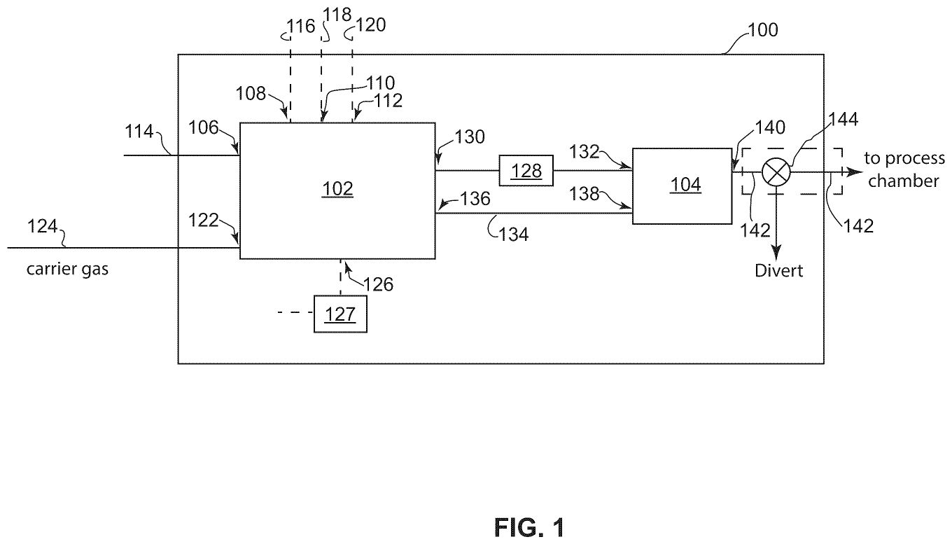

FIG. 1 illustrates a block diagram of modular vapor delivery system 100, comprising flow control component module 102 and vaporizer module 104. Modular vapor delivery system 100 may be delineated by the rectangle enclosing flow control component module 102 and vaporizer module 104. In at least one implementation, flow control component module 102 and vaporizer module 104 may be mounted on a board or base plane. In at least one implementation, flow control component module 102 and vaporizer module 104 may be mounted on a platform within an enclosure (e.g., a cabinet).

In at least one implementation, modular vapor delivery system 100 may comprise high-temperature materials having substantial resistance to corrosive chemicals. In at least one implementation, components of the modular vapor delivery system may comprise materials such as, but not limited to, stainless steel, or high-temperature nickel alloys such as Hastelloy. Other suitable materials, such as metal alloys comprising titanium, tungsten, or tantalum may also be included, in accordance with at least one embodiment. In at least one implementation, the substrate may comprise high-temperature chemically resistant polymers such as polyether ether ketone (PEEK) or fluoropolymers (e.g., Teflon).

In at least one implementation, flow control component module 102 may comprise one or more liquid flow control components such as, but not limited to, valves, liquid mass flow controllers, and gas mass flow controllers (not shown). In at least one implementation, flow control components module 102 may comprise a surface mount substrate on which surface-mountable flow control components such as valves, and gas, and/or liquid mass flow controllers may be mounted and interconnected. In at least one implementation, the surface mount substrate may comprise a plurality of apertures on a mounting surface. In at least one implementation, apertures may enable fluidic communication between the liquid flow control components and multiple gas flow paths within the surface mount substrate.

In at least one implementation, valves and mass flow controllers may be interconnected by swage fittings and metal tubing. In at least one implementation, flow control component module 102 may comprise one or more inlet ports 106, 108, 110, and 112, where inlet ports 106-112 may be coupled to a source of a liquid precursor substance through liquid delivery lines 114, 116, 118, and 120. In at least one implementation, any or all liquid delivery lines 114-120 may not be connected. In the illustrated implementation, liquid delivery lines 116, 118, and 120 are represented by dashed lines to indicate that they may be connected as desired. In at least one implementation, liquid delivery line 114 may be connected to a liquid source, described below.

In at least one implementation, multiple pure precursor substances may be delivered to modular vapor delivery system and mixed within. In at least one implementation, any or all liquid delivery lines 116-120 may be employed for introduction of the multiple pure liquid precursor species into flow control component module 102. In at least one implementation, pure liquid precursor species may be mixed directly by mixing components on flow control component module 102.

In at least one implementation, flow control component module 102 may comprise inlet port 122 for introduction of carrier gas through gas delivery line 124. In at least one implementation, flow control component module 102 further comprises an additional inlet port 126 for introduction of liquid precursor species or mixture. In at least one implementation, inlet ports 106, 108, 110, 112, 122 and 126 may be swage fittings connected to tubing.

In at least one implementation, degas module 127 is coupled to inlet port 126 on-board modular vapor delivery system 100. In at least one implementation, degas module 127 may be coupled to any of the inlet ports 106, 108, 110, 112, 122 or 126. In at least one implementation, multiple degas modules (not shown) may be deployed on-board modular vapor delivery system 100. In at least one implementation, degas module 127 may remove dissolved gases from liquid precursors entering flow control component module 102.

In at least one implementation, liquid flow controller (LFC) 128 may be coupled to outlet port 130 of flow control component module 102, and to inlet port 132 of vaporizer module 104. In at least one implementation, carrier gas line 134 comprises a first terminal coupled to outlet port 136 of flow control component module 102, and a second terminal coupled to inlet port 138 of vaporizer module 104.

In at least one implementation, vaporizer module 104 may be operable to mix a liquid precursor mixture entering inlet port 132 and a carrier gas entering inlet port 138. In at least one implementation, a liquid precursor mixture may be premixed by flow control component module 102 with carrier gas entering through inlet port 122, before entering vaporizer module 104. In at least one implementation, premixed precursor mixture may still be further mixed and diluted by carrier gas entering vaporizer module 104 through inlet port 138. In at least one implementation, flow rates of carrier gases may be adjusted to obtain precise concentrations of precursor species in a precursor stream or multicomponent precursor mixture stream.

In at least one implementation, vaporizer module 104 comprises a heating chamber (not shown) to cause rapid vaporization of a one-component or multicomponent liquid stream entering at inlet port 132, for example. In at least one implementation, vaporizer module 104 may be operable to vaporize substantially all liquid entering its heating chamber, enabling the abundance ratio (e.g., molar, mass, or volumetric ratio) of a multicomponent precursor vapor to be substantially the same as the abundance ratio of the vaporized liquid stream. In at least one implementation, vaporizer module 104 may be operable to mix vapors with a carrier gas entering at inlet port 138, enabling adjustment of the concentrations of the precursor species. In at least one implementation, a gas stream comprising precursor vapor and carrier gas may exit vaporizer module 104 at outlet port 140.

In at least one implementation, a heated vapor delivery line 142 (enclosed in the dashed box) may be coupled to outlet port 140 and to a process chamber (not shown). In at least one implementation, a heating jacket or heating tape may be wrapped or enclosed over heated vapor delivery line 142. In at least one implementation, heating tape or heating jacket may be electrically coupled to a temperature controller. In at least one implementation, a feedback circuit for a temperature controller may comprise temperature sensors such as thermocouples and resistance temperature detectors (RTDs). In at least one implementation, flow control components and lines in modules upstream of the vaporizer module may handle liquids. Liquid handling generally can be performed at room temperature, thus temperature control of the upstream modules may be superfluous. In at least one implementation, confinement of heating and temperature control to a conduit may enable significant cost savings and design simplification of the modular vapor delivery system.

In at least one implementation, a divert valve 144 may be connected in line with outlet port 140 of vaporizer module 104 and heated vapor delivery line 142. Divert valve 144 may be coupled to a vacuum system comprising a vacuum pump (not shown). In at least one implementation, divert valve 144 may be employed to divert the precursor vapor stream to the vacuum, for example, to mitigate pressure transients that may occur when gas flow is started. In at least one implementation, divert valve 144 may be closed to resume flow of the precursor stream to a process chamber when the flow reaches steady state, for example.

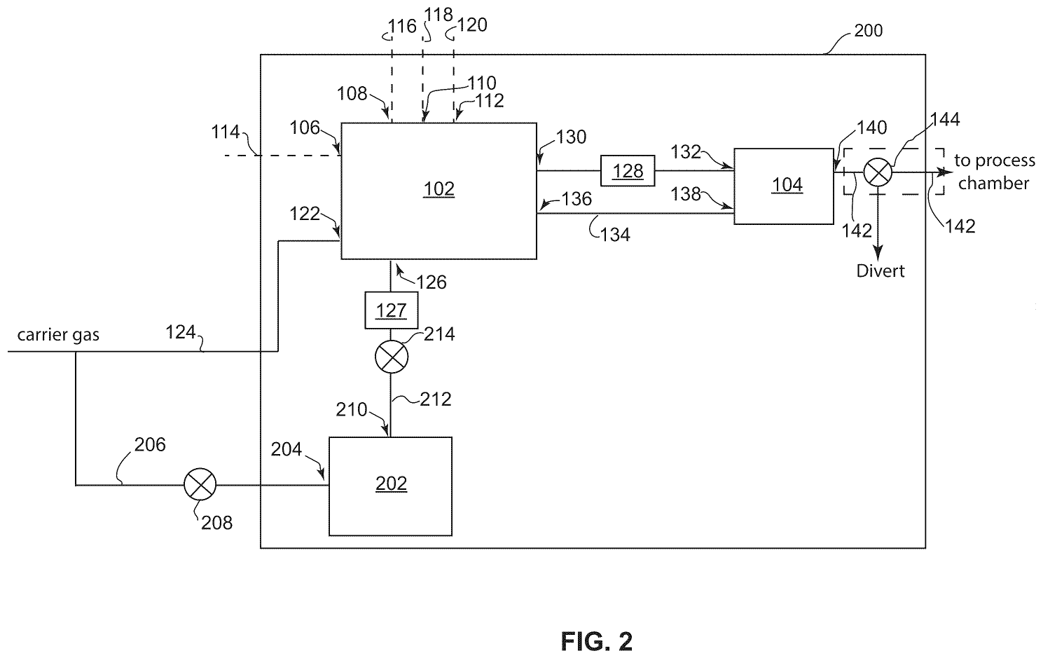

FIG. 2 illustrates a block diagram of modular vapor delivery system 200, comprising chemistry ampoule 202, internally coupled to flow control component module 102, in accordance with at least one implementation. In at least one implementation, chemistry ampoule 202 may be a vessel or reservoir operable to contain a liquid precursor. In at least one implementation, chemistry ampoule 202 may be operable to receive a carrier gas stream through inlet port 204. In at least one implementation, inlet port 204 may be fed by gas delivery line 206. In at least one implementation, valve 208 may be coupled in-line with gas delivery line 206 to regulate flow of carrier gas or inert gas into chemistry ampoule 202. In at least one implementation, carrier or inert gas may pressurize the liquid contents of chemistry ampoule 202.

In at least one implementation, chemistry ampoule 202 may be mounted on the same platform employed for mounting other modules of modular vapor delivery system 200. In at least one implementation, chemistry ampoule 202 may be included within a common enclosure housing modular vapor delivery system 200. In at least one implementation, chemistry ampoule 202 is removable for maintenance or for recharging precursor.

In at least one implementation, chemistry ampoule 202 may comprise outlet port 210. Liquid delivery line 212 may be coupled to outlet port 210 and to inlet port 126 of flow control component module 102. In at least one implementation, valve 214 may be coupled in-line with liquid delivery line 212. Valve 214 may enable metering of liquid precursor into flow control component module 102. In at least one implementation, degas module 127 may be in-line with liquid delivery line 212, between chemistry ampoule 202 and inlet port 126.

In at least one implementation, modular vapor delivery system 200 may be substantially similar to modular vapor delivery system 100. For example, the description of the precursor flow path comprising flow control component module 102 and vaporizer module 104 may be substantially as described for modular vapor delivery system 100.

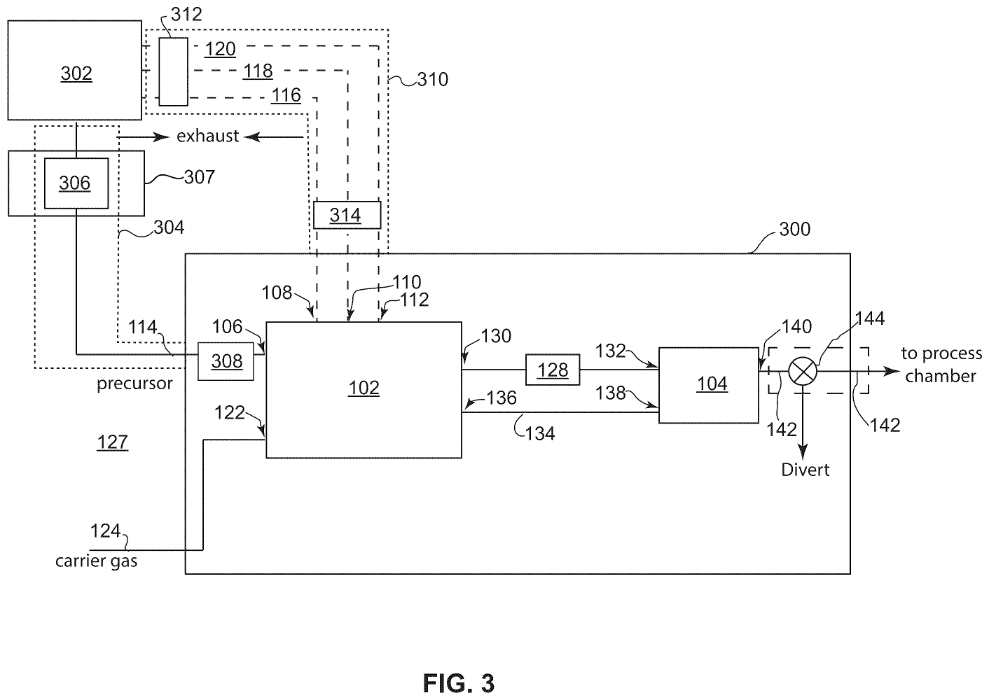

FIG. 3 illustrates a block diagram of modular vapor delivery system 300. In the illustrated implementation, the precursor is supplied to modular vapor delivery system 300 by chemistry storage and delivery unit (CSDU) 302, in accordance with at least one implementation. In at least one implementation, CSDU 302 may be external to modular vapor delivery system 300. In at least one implementation, CSDU 302 comprises one or more precursor reservoirs (not shown). In at least one implementation, the one or more precursor reservoirs may be substantially similar to chemistry ampoule 202. In at least one implementation, the one or more precursor reservoirs may be operable to store one-component liquid precursor compounds. In at least one implementation, the one or more precursor reservoirs may be operable to store multicomponent precursor mixtures.

In at least one implementation, CSDU 302 may comprise a batch premixing stage (not shown) to pre-combine multiple liquid precursor compounds in prescribed abundance ratio (e.g., molar, mass, or volumetric percentage ratio), for example. In at least one implementation, CSDU 302 may comprise a continuous flow mixing stage, comprising active pumping, and an in-line mixer, for example. In at least one implementation, CSDU 302 may output a precursor mixture through liquid delivery line 114. In at least one implementation, liquid delivery line 114 may be routed through exhaust duct 304, shown with a stippled outline. In at least one implementation, exhaust duct 304 is coupled to a cabinet enclosure for modular vapor delivery system 300. In at least one implementation, exhaust duct 304 may also be coupled to an exhaust ventilation system to provide a negative pressure within the enclosure. In at least one implementation, exhaust duct 304 may enable the exhaust system to remove precursor vapors that may have leaked into the enclosure. Such vapors may escape into the ambient and become a toxicity hazard to exposed personnel in the vicinity of the tool.

In at least one implementation, a lockout tagout (LOTO) valve 306 may be coupled in-line with liquid delivery line 114. In at least one implementation, LOTO valve 306 may be a shut-off valve, employed to isolate modular vapor delivery system 300 from CSDU 302. For example, LOTO valve 306 may be employed for maintenance or emergency purposes. In at least one implementation, LOTO valve 306 may be in an easily accessible area of the process tool. As LOTO valve 306 is in-line with liquid delivery line 114 that is routed within exhaust duct 304, in at least one implementation, LOTO valve 306 may be housed within enclosure 307 that is coupled to exhaust duct 304. In at least one implementation, enclosure 307 may be hermetically sealed, and comprises a removable cover for access to LOTO valve 306.

In at least one implementation, degas module 308 may be coupled in-line with liquid delivery line 114. In at least one implementation, degas module 308 may be located on-board modular vapor delivery system 300. In at least one implementation, degas module 308 may enable removal of dissolved inert gases from the liquid precursors or liquid precursor mixture entering liquid delivery line 114.

In at least one implementation, CSDU 302 may supply multiple precursor compounds as one-component streams that flow within liquid delivery lines 116, 118, and 120 to modular vapor delivery system 300. In at least one implementation, liquid delivery lines 116, 118, and 120 may supplement liquid delivery line 114. As noted above, liquid delivery lines 116, 118, and 120 may be directly coupled to flow control component module 102. In at least one implementation, liquid delivery lines 116, 118, and 120 may be routed together through exhaust duct 310. In at least one implementation, exhaust duct 310 may be coupled to modular vapor delivery system 300 to evacuate any leaked vapors that may otherwise accumulate, for example, within an enclosure holding modular vapor delivery system 300. In at least one implementation, exhaust duct 310 may be coupled to a ventilation system.

In at least one implementation, LOTO valve 312 may be coupled to liquid delivery lines 116, 118, and 120. LOTO valve 312 may be employed to decouple modular vapor delivery system 300 from CSDU 302 by manual or automated control. In at least one implementation, LOTO valve 312 may be employed for maintenance and emergency response to a vapor leak, for example.

In at least one implementation, degas module 314 may be coupled to liquid delivery lines 116, 118, and 120. In at least one implementation, degas module 314 is on-board modular vapor delivery system 300. In at least one implementation, degas module 314 may represent multiple degas modules. In at least one implementation, degas module 314 may be operable to degas multiple liquid streams simultaneously.

In at least one implementation, liquid delivery lines 114, 116, 118, and 120 may be routed together through exhaust duct 304, omitting exhaust duct 310, LOTO valve 312 and degas module 314.

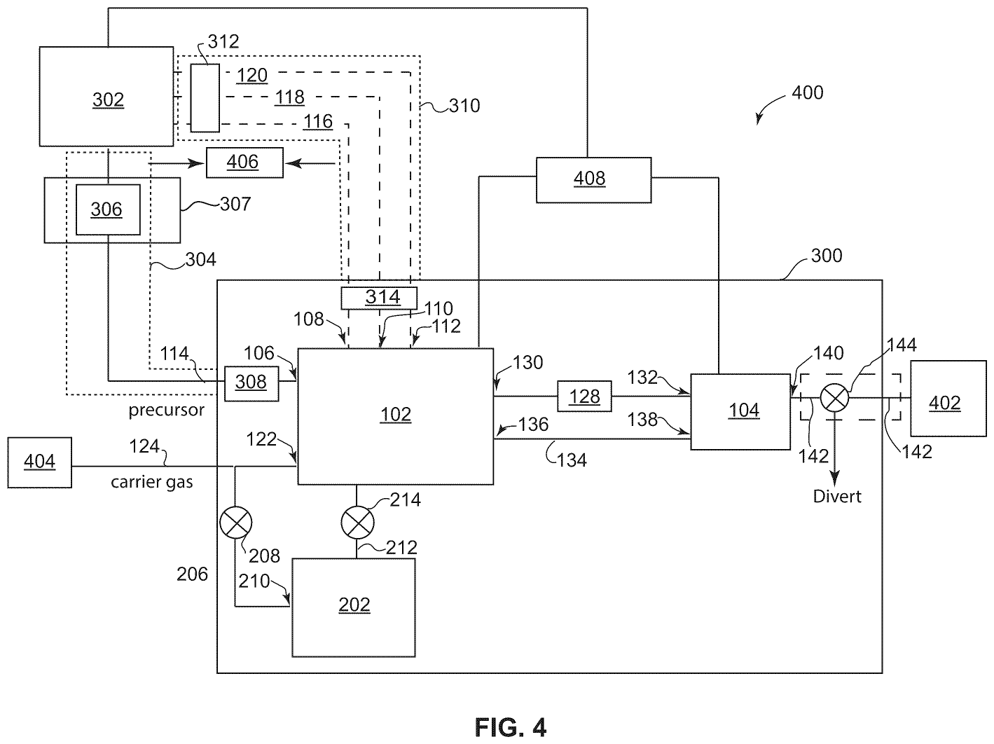

FIG. 4 illustrates a block diagram for system 400, comprising modular vapor delivery system 300 coupled to process chamber 402, in accordance with at least one implementation. In at least one implementation, modular vapor delivery system 300 may be substantially as described as above. In at least one implementation, CSDU 302 and chemistry ampoule 202 are both coupled to flow control component module 102 to indicate versatility of modular vapor delivery system 300, including modular vapor delivery systems 100 and 200. While both CSDU 302 and chemistry ampoule 202 are employed as precursor storage systems, one or both precursor storage systems may be operational.

In at least one implementation, process chamber 402 may be a high vacuum or ultra-high vacuum chamber included within a semiconductor process tool. In at least one implementation, semiconductor integrated circuit manufacturing processes such as chemical vapor deposition, etching, or cleaning may be performed within process chamber 402. In at least one implementation, process chamber 402 comprises a gas distribution showerhead (not shown), which may be coupled to vaporizer module 104. In at least one implementation, the showerhead is operational to be temperature controlled. While the illustrated implementation of system 400 comprises modular vapor delivery system 300, modular vapor delivery systems 100 and 200 may be equally employed to deliver precursor vapors to process chamber 402.

In at least one implementation, process chamber 402 is coupled to modular vapor delivery system 300 by heated vapor delivery line 142. In at least one implementation, heated vapor delivery line 142 may be substantially as described above. As noted above, vaporizer module 104 may be the final stage of modular vapor delivery system 300 (equally, modular vapor delivery systems 100 or 200). As noted previously, the placement of vaporizer module 104 as the final stage of modular vapor delivery system 300 may economize on cost and complexity of system 400. In at least one implementation, system heating may be confined to heated vapor delivery line 142.

In at least one implementation, system 400 may comprise carrier gas source 404 coupled to gas delivery line 124. In at least one implementation, carrier gas source 404 may supply inert or reactive gas as carrier gases, or pressurization gases for all stages or modular vapor delivery system 300. In at least one implementation, gases from carrier gas source 404 may flow into process chamber 402.

In at least one implementation, system 400 may comprise exhaust system 406, to which exhaust duct 304 and/or exhaust duct 310 may be coupled.

In at least one implementation, system 400 may comprise processor 408 for automated control. In at least one implementation, processor 408 may be electrically coupled to flow control component module 102 and vaporizer module 104. In at least one implementation, processor 408 may be coupled to CSDU 302. In at least one implementation, processor 408 may coordinate operation of flow control components within flow control component module 102 and vaporizer module 104, for example.

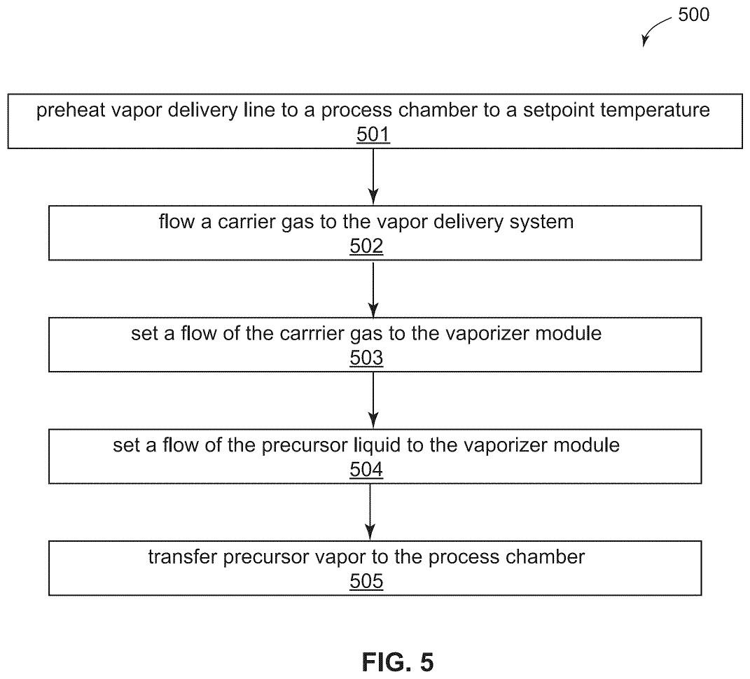

FIG. 5 illustrates a process flow chart 500 illustrating an exemplary method for operating a modular vapor delivery system according to at least one implementation of the disclosure, such as modular vapor delivery system 300.

In at least one implementation, in block 501, the modular vapor delivery system is connected to a process chamber, such as process chamber 402 of a semiconductor process tool. In at least one implementation, process chamber is a high vacuum or ultra-high vacuum chamber wherein semiconductor chip manufacturing processes may be performed. In at least one implementation, processes such as chemical vapor deposition, deep reactive ion etching, or plasma cleaning may be performed within the process chamber. In at least one implementation, deposition or etching processes may employ mixtures of precursor substances or reactive substances in prescribed concentrations and abundance ratios.

In at least one implementation, such processes are performed under high or ultra-high vacuum conditions. In at least one implementation, a gas distribution showerhead receives and distributes vapors (e.g., of deposition precursors) and reactive or inert gases within the process chamber. In at least one implementation, vapors and gases may issue from orifices within a faceplate of the showerhead. In at least one implementation, faceplate of the showerhead may be located directly overhead of a wafer substrate held in a chuck on a pedestal within the process chamber.

In at least one implementation, a heated vapor delivery line (e.g., heated vapor delivery line 142) may be coupled to the vapor outlet port of a vaporizer module (e.g., outlet port 140 of vaporizer module 104) on the modular vapor delivery system. In at least one implementation, vaporizer module may be the final stage of the modular vapor delivery system. In at least one implementation, forestages and forelines within the modular vapor delivery system relative to the vaporizer module stage may exclusively transport and handle liquids or carrier gases and are not heated. In at least one implementation, configuration of the modular vapor delivery system may enable cost savings and design simplicity. As such, heating may be confined to the heated vapor delivery line to maintain precursor substances, once vaporized by the vaporizer module, in the gas phase.

In at least one implementation, vaporizer module may supply sufficient heat to substantially vaporize all components of the precursor mixture. In at least one implementation, by substantially complete vaporization, the abundance ratio (e.g., molar, weight, or volume ratio) of the components of the liquid mixture may be substantially the same in the vapor phase. In at least one implementation, the vaporizer module may enable reliable introduction of precursor vapor mixtures having precise abundance ratios into the process chamber.

In at least one implementation, the heated vapor delivery line may be heated by a heating tape wrap or by a coil of heating wire (e.g., nichrome wire). In at least one implementation, heated vapor delivery line may be covered by a heated blanket or heating jacket. In at least one implementation, heated vapor delivery line may be preheated to a setpoint temperature that is programmed into a temperature controller, for example. In at least one implementation, temperature sensors embedded within the heated vapor delivery line, for example, may provide a feedback signal to the temperature controller. In at least one implementation, for a precursor mixture, the setpoint temperature of the heated vapor delivery line may be determined by the highest boiling point or sublimation point of the mixture precursor components to ensure that all components remain in the vapor state.

In at least one implementation, heated vapor delivery line may be heated to highest vaporization temperature to mitigate cold spots and eliminate condensation or crystallization of precursor components to the liquid or solid state within the heated vapor delivery line before entering within the process chamber. In at least one implementation, condensation or crystallization of precursor species within the heated delivery line may cause random and unwanted changes to the abundance ratio of remaining vapor. In addition, condensation and crystallization may cause clogging of the line. In at least one implementation, lines within the process chamber may also be heated, as well as the showerhead, to prevent potential condensation or crystallization of precursor species from clogging orifices of the showerhead and potential loss of abundance ratio.

In at least one implementation, in block 502, a carrier gas is introduced into the modular vapor delivery system. In at least one implementation, a carrier gas source (e.g., carrier gas source 404) may be coupled to inlet port 122 of flow control component module 102, as shown in FIG. 4. In at least one implementation, carrier gas may be inert, such as argon or nitrogen, or reactive, such as oxygen, hydrogen, hydrazine, ammonia, ozone, or water vapor. In at least one implementation, the flow rate of the carrier gas may be set by valves or by a mass flow controller, for example, within flow control component module 102.

In at least one implementation, in block 503, a flow rate of carrier gas to the vaporizer module is set. In at least one implementation, carrier gas source 404 of system 400 may be the primary supply of carrier gas for the system. In at least one implementation, carrier gas may be supplied to, and distributed within an external precursor supply (e.g., CSDU 302) by carrier gas source 404, for example. In at least one implementation, CSDU 302 may comprise a separate carrier gas source to force flow of precursor streams, for example. In at least one implementation, carrier gas may flow from carrier gas source 404, for example, into vaporizer module 104 through flow control component module 102. In at least one implementation, flow rate of the carrier gas exiting flow control components module 102 at outlet port 136 may be set by a valve or mass flow controller, for example. In at least one implementation, within vaporizer module 104, the carrier gas may flow at the preset flow rate and dilute precursor vapors, formed in a stream, to a substantially precise concentration ratio.

In at least one implementation, in block 504, flow rate of precursor liquid to vaporizer module 104 is set. In at least one implementation, a pulsed, continuous or semi-continuous flow of a liquid stream comprising one or more precursor components may be set in motion. In at least one implementation, precursor stream may be set in motion by pressurization of a chemistry ampoule containing a component or multi-component precursor liquid (e.g., chemistry ampoule 202), or by pressurization of containment vessels similar to chemistry ampoule 202 on CSDU 302. In at least one implementation, CSDU 302 comprises an active pumping system for generation of continuous precursor flow. In at least one implementation, liquid flow controller (LFC) 128 may primarily determine the liquid flow rate of the liquid precursor stream that enters vaporizer module 104 after passage through flow control component module 102.

In at least one implementation, within vaporizer module 104, the carrier gas stream and liquid precursor stream may converge and flow into a heating chamber within vaporizer module 104. In at least one implementation, heating chamber may supply sufficient heat to continuously vaporize all the liquid stream entering therein. In at least one implementation, precursor vapors generated within the heating chamber may mix by turbulence with the carrier gas stream, whereby the precursor vapors are diluted by the carrier gas. In at least one implementation, flow rates of the liquid precursor stream and the carrier gas stream may be respectively set by LFC 128 and a mass flow controller within the flow control component module 102.

In at least one implementation, in block 505, precursor vapors diluted within a carrier gas may be transferred to process chamber 402 via heated vapor delivery line 142. As noted above, heated vapor delivery line 142 may be heated to a setpoint temperature corresponding to the highest vaporization temperature of the precursor mixture. In at least one implementation, setpoint temperature may be controlled by a temperature controller. In at least one implementation, setting the temperature of the heated vapor delivery line to the highest vaporization temperature may mitigate condensation to the liquid state or crystallization to the solid state of precursor components within a mixture, for example. In at least one implementation, abundance ratio may be maintained during transit to the process chamber, and line clogging may be avoided.

In at least one implementation, vapors may transfer from heated vapor delivery line 142 to a showerhead within process chamber 402. In at least one implementation, gas and vapor delivery lines within process chamber 402, as well as the showerhead itself, may be heated to mitigate risk of precursor condensation or crystallization within the showerhead. In at least one implementation, condensation of precursor vapor streams may also be avoided. In at least one implementation, condensation of a precursor vapor within the showerhead may force liquid droplets into the process chamber during a chemical vapor deposition process. In at least one implementation, liquid droplets may cause defects in a growing monocrystalline or polycrystalline film, for example.

The following examples are provided that illustrate the various implementations. The examples can be combined with other examples. As such, various implementations can be combined with other implementations without changing the scope of the invention.

Example 1 is a modular vapor delivery system, comprising a flow control component module comprising a first inlet port and a second inlet port a liquid flow controller coupled to a first outlet port of the flow control component module; and a vaporizer module coupled to a second outlet port of the liquid flow controller.

Example 2 is the modular vapor delivery system of any example herein, particular example 1, wherein a divert valve is coupled to a third outlet port of the vaporizer module.

Example 3 is the modular vapor delivery system of any example herein, particular example 1, wherein a first carrier gas line is coupled to the first inlet port of the flow control component module.

Example 4 is the modular vapor delivery system of any example herein, particular example 3, wherein a second carrier gas line is coupled to a fourth outlet port of the flow control component module and wherein the second carrier gas line is coupled to the vaporizer module.

Example 5 is the modular vapor delivery system of any example herein, particular example 4, further comprising a chemistry ampoule, wherein the chemistry ampoule is coupled to the second inlet port of the flow control component module.

Example 6 is the modular vapor delivery system of any example herein, particular example 5, wherein a first valve is coupled to the chemistry ampoule and wherein the first valve is coupled to the second inlet port of the flow control component module.

Example 7 is the modular vapor delivery system of any example herein, particular example 6, wherein a second valve is coupled to a third inlet port of the chemistry ampoule.

Example 8 is the modular vapor delivery system of any example herein, particular example 7, wherein a third carrier gas line is coupled to the second valve.

Example 9 is the modular vapor delivery system of any example herein, particular example 1, wherein a chemistry storage and delivery unit are coupled to the second inlet port of the flow control component module.

Example 10 is the modular vapor delivery system of any example herein, particular example 9, wherein a liquid delivery line is coupled to the chemistry storage and delivery unit and to the second inlet port of the flow control component module.

Example 11 is the modular vapor delivery system of any example herein, particular example 10, wherein the liquid delivery line is routed within an exhaust duct, and wherein the exhaust duct is coupled to an enclosure housing the flow control component module.

Example 12 is the modular vapor delivery system of any example herein, particular example 11, wherein a degas module is coupled in-line to the liquid delivery line.

Example 13 is the modular vapor delivery system of any example herein, particular example 12, wherein a lockout tagout (LOTO) valve is coupled to the liquid delivery line.

Example 14 is the modular vapor delivery system of any example herein, particular example 13, wherein the LOTO valve is housed within an enclosure that is coupled to the exhaust duct, and wherein the enclosure is sealed.

Example 15 is a system, comprising a process chamber; and a modular vapor delivery system coupled to the process chamber, wherein the modular vapor delivery system comprises a flow control component module comprising a first inlet port and a second inlet port, a liquid flow controller coupled to a first outlet port of the flow control component module; and a vaporizer module coupled to a second outlet port of the liquid flow controller.

Example 16 is the system of any example herein, particular example 15, wherein a divert valve is coupled to a third outlet port of the vaporizer module and to a vacuum pump.

Example 17 is the system of any example herein, particular example 15, wherein the flow control component module comprises a mass flow controller coupled to an inert gas line.

Example 18 is a method comprising providing a modular vapor delivery system, wherein the modular vapor delivery system comprises a flow control component module comprising a first inlet port and a second inlet port; a liquid flow controller coupled to a first outlet port of the flow control component module; and a vaporizer module coupled to a second outlet port of the liquid flow controller; preheating a heated vapor delivery line to a setpoint temperature, wherein the heated vapor delivery line is coupled to the vaporizer module and to a process chamber; flowing an inert gas to the modular vapor delivery system; setting a first flow rate of the inert gas to the vaporizer module; and setting a second flow rate of a precursor liquid to the vaporizer module.

Example 19 is the method of any example herein, particular example 18, wherein flowing the inert gas to the modular vapor delivery system comprises setting a mass flow controller coupled to an inert gas line and to the vaporizer module.

Example 20 is the method of any example herein, particular example 18, wherein setting the second flow rate of the precursor liquid to the vaporizer module comprises setting the liquid flow controller, wherein the liquid flow controller is coupled to the flow control component module and is coupled to the vaporizer module.

Besides what is described herein, various modifications may be made to the disclosed implementations and implementations thereof without departing from their scope. Therefore, illustrations of implementations herein should be construed as examples only, and not restrictive to the scope of the present disclosure. The scope of the invention should be measured solely by reference to the claims that follow.

We claim:

1. A modular vapor delivery system, comprising:
a flow control component module comprising a first inlet port and a second inlet port;
a liquid flow controller coupled to a first outlet port of the flow control component module; and
a vaporizer module coupled to a second outlet port of the liquid flow controller.

2. The modular vapor delivery system of claim 1, wherein a divert valve is coupled to a third outlet port of the vaporizer module.

3. The modular vapor delivery system of claim 1, wherein a first carrier gas line is coupled to the first inlet port of the flow control component module.

4. The modular vapor delivery system of claim 3, wherein a second carrier gas line is coupled to a fourth outlet port of the flow control component module and wherein the second carrier gas line is coupled to the vaporizer module.

5. The modular vapor delivery system of claim 4, further comprising a chemistry ampoule, wherein the chemistry ampoule is coupled to the second inlet port of the flow control component module.

6. The modular vapor delivery system of claim 5, wherein a first valve is coupled to the chemistry ampoule and wherein the first valve is coupled to the second inlet port of the flow control component module.

7. The modular vapor delivery system of claim 6, wherein a second valve is coupled to a third inlet port of the chemistry ampoule.

8. The modular vapor delivery system of claim 7, wherein a third carrier gas line is coupled to the second valve.

9. The modular vapor delivery system of claim 1, wherein a chemistry storage and delivery unit are coupled to the second inlet port of the flow control component module.

10. The modular vapor delivery system of claim 9, wherein a liquid delivery line is coupled to the chemistry storage and delivery unit and to the second inlet port of the flow control component module.

11. The modular vapor delivery system of claim 10, wherein the liquid delivery line is routed within an exhaust duct, and wherein the exhaust duct is coupled to an enclosure housing the flow control component module.

12. The modular vapor delivery system of claim 11, wherein a degas module is coupled in-line to the liquid delivery line.

13. The modular vapor delivery system of claim 12, wherein a lockout tagout (LOTO) valve is coupled to the liquid delivery line.

14. The modular vapor delivery system of claim 13, wherein the LOTO valve is housed within an enclosure that is coupled to the exhaust duct, and wherein the enclosure is sealed.

15. A system, comprising:
a process chamber; and
a modular vapor delivery system coupled to the process chamber, wherein the modular vapor delivery system comprises:
a flow control component module comprising a first inlet port and a second inlet port;
a liquid flow controller coupled to a first outlet port of the flow control component module; and
a vaporizer module coupled to a second outlet port of the liquid flow controller.

16. The system of claim 15, wherein a divert valve is coupled to a third outlet port of the vaporizer module and to a vacuum pump.

17. The system of claim 15, wherein the flow control component module comprises a mass flow controller coupled to an inert gas line.

18. A method, comprising:
providing a modular vapor delivery system, wherein the modular vapor delivery system comprises:
a flow control component module comprising a first inlet port and a second inlet port;
a liquid flow controller coupled to a first outlet port of the flow control component module; and
a vaporizer module coupled to a second outlet port of the liquid flow controller;
preheating a heated vapor delivery line to a setpoint temperature, wherein the heated vapor delivery line is coupled to the vaporizer module and to a process chamber;
flowing an inert gas to the modular vapor delivery system;
setting a first flow rate of the inert gas to the vaporizer module; and
setting a second flow rate of a precursor liquid to the vaporizer module.

19. The method of claim 18, wherein flowing the inert gas to the modular vapor delivery system comprises setting a mass flow controller coupled to an inert gas line and to the vaporizer module.

20. The method of claim 18, wherein setting the second flow rate of the precursor liquid to the vaporizer module comprises setting the liquid flow controller, wherein the liquid flow controller is coupled to the flow control component module and is coupled to the vaporizer module.
